(19) United States
(12) Patent Application Publication
(10) Pub. No.: US 2026/0040856 A1
(43) Pub. Date: Feb. 5, 2026

(54) DIE ATTACH FILM INDIVIDUALIZATION BEFORE WAFER DICING

(71) Applicant: Texas Instruments Incorporated, Dallas, TX (US)

(72) Inventors: Hiroyuki Sada, Beppu (JP); Mao Sugeno, Beppu (JP)

(21) Appl. No.: 18/789,956

(22) Filed: Jul. 31, 2024

(51) Int. Cl. H01L 21/78; H01L 23/00; H01L 23/31; H01L 23/495

(52) U.S. Cl. CPC H01L 21/78; H01L 23/3107; H01L 23/49541; H01L 24/32; H01L 24/95; H01L 24/48; H01L 24/73; H01L 2224/32245; H01L 2224/48245; H01L 2224/73265; H01L 2224/95001

(57) ABSTRACT

An electronic device includes a conductive lead, a semiconductor die, a package structure enclosing the semiconductor die and a portion of the conductive lead, and a non-conductive die attach film extending between the conductive lead and the semiconductor die, with a lateral side of the semiconductor die extending beyond an end of the die attach film by a non-zero gap distance. A method of fabricating an electronic device includes performing a first singulation process that separates portions of a die attach film on a wafer, performing a second singulation process that separates a semiconductor die from the wafer having a portion of the die attach film, and attaching the semiconductor die to a lead frame with the die attach film extending between a prospective lead portion and the side of the semiconductor die.

### BACKGROUND

Reduced electronic device package sizes is important for many applications, and often inhibits the ability to provide a dedicated die attach pad (DAP) for supporting a semiconductor die. Chip on lead (COL) designs have a die mounted to a lead and may use nonconductive die attach film (DAF) to isolate the die from a voltage signal of the attached lead. However, silicon particles remaining in or alongside the die attach film from a die or DAF singulation process can cause shorts or leakage between the lead and the attached die.

### SUMMARY

In one aspect, an electronic device includes a conductive lead, a semiconductor die, a package structure enclosing the semiconductor die and a portion of the conductive lead, and a non-conductive die attach film extending between the conductive lead and the semiconductor die, with a lateral side of the semiconductor die extending beyond an end of the die attach film by a non-zero gap distance.

In another aspect, a system includes a circuit board with a conductive feature and an electronic device that includes a conductive lead connected to the conductive feature of the circuit board, a semiconductor die, a package structure enclosing the semiconductor die and a portion of the conductive lead, and a non-conductive die attach film extending between the conductive lead and the semiconductor die, wherein a lateral side of the semiconductor die extending beyond an end of the non-conductive die attach film by a non-zero gap distance.

In a further aspect, a method of fabricating an electronic device includes performing a first singulation process that separates portions of a die attach film on a wafer, performing a second singulation process that separates a semiconductor die from the wafer having a portion of the die attach film, and attaching the semiconductor die to a lead frame with the die attach film extending between a prospective lead portion and the side of the semiconductor die.

### BRIEF DESCRIPTION OF THE DRAWINGS

FIG. 1 is a partial sectional side elevation view of a chip on lead electronic device including a semiconductor die with an edge laterally overhanding past a die attach adhesive a taken along line 1-1 of FIG. 1A.

FIG. 1A is a top plan view of the electronic device of FIG. 1.

FIG. 2 is a flow diagram of a method of making an electronic device.

FIGS. 3-17 are partial sectional side elevation views of the electronic device of FIGS. 1 and 1A undergoing fabrication processing according to the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means+/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for case of description in connection with a particular drawing, where such are not to be construed as limiting with respect to the claims. Various structures and methods of the present disclosure may be beneficially applied to an electronic device or apparatus such as an integrated circuit and to manufacturing electronic devices. While such examples may be expected to provide various improvements, no particular result is a requirement of the present disclosure unless explicitly recited in a particular claim.

Remaining silicon particles in or alongside die attach film after a singulation process can cause shorts or leakage between the lead and the attached die in chip on lead (COL) devices. Incomplete separation of die attach film portions during singulation can also lead to manufacturing defects and worsen isolation between the die and the lead. Blade dicing, also referred to as saw cutting, uses a cutting blade to cut through and ideally separate a semiconductor die and associated die attach film from a starting wafer structure. However, the cutting blade often causes mechanical stress and damage while cutting through silicon of a wafer that can generate silicon splinters or particles, which can be embedded in or along a side of the die attach film. Once the singulated die is attached to a lead of a chip on lead device, the silicon particles can lead to leakage or short circuit conditions between the silicon of the die and the conductive lead structure. Stealth dicing or other separation processing using a laser cuts through or creates fractures within the silicon material of a wafer, and stretching a dicing tape creates a lateral separation forced to separate the dies from the starting wafer structure. However, the stealth dicing operation may not directly act on the die attach film, and the die attach film separation largely depends on mechanical stress during dicing tape stretching. However, the die attach film separating force can be significant for small die sizes, which can impact the structural integrity and performance of the semiconductor die and can also lead to formation of silicon particles in or alongside the dic attach film after singulation processing. Plasma dicing uses plasma sustained etching to separate semiconductor dies from the wafer. However, the etch processing is generally optimized for removing silicon and is inefficient for etching through the die attach film. This leads to excessive processing and increased manufacturing costs. In addition, etch processing can deteriorate the die attach film material as well as the dicing tape, resulting in tape damage. Etch-based singulation therefore suffers from low productivity and high cost, as well as low process yield.

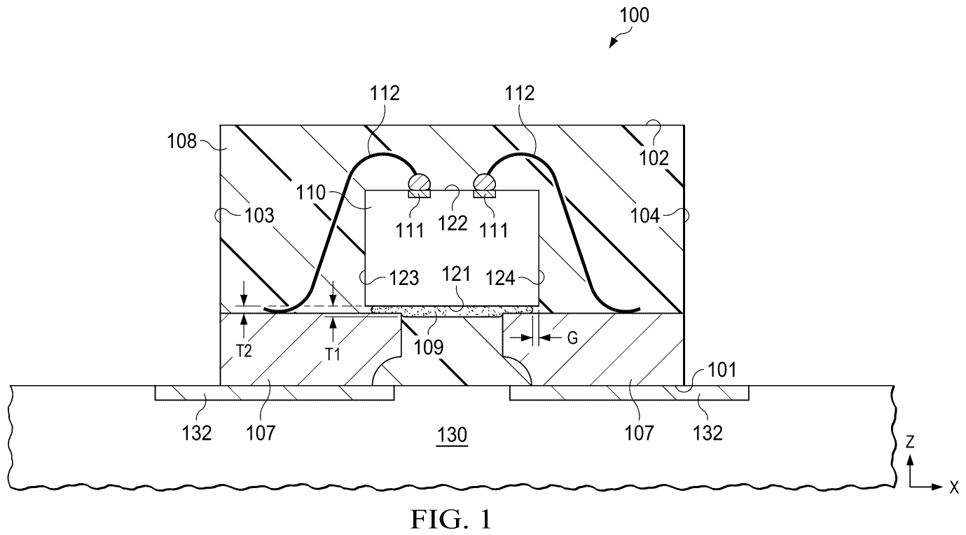

Referring initially to FIGS. 1 and 1A, described examples include packaged electronic devices, systems and fabrication methods for chip on lead and other types of electronic devices by separate singulation processing for die attach film separation on a wafer and subsequent die singulation processing to separate electronic devices from a starting wafer. FIGS. 1 and 1A show sectional side and top views of an example electronic device 100. The electronic device 100 can be an integrated circuit (IC) with two or more electronic components (e.g., resistors, transistors, diodes, capacitors, etc.), or an electronic device with a single electronic component. The electronic device 100 is shown in an example three-dimensional space with a first direction X, a perpendicular (orthogonal) second direction Y (FIG. 1A), and a third direction Z (FIG. 1) that is perpendicular (orthogonal) to the first and second directions X and Y. Structures or features along any two of these directions are orthogonal to one another. The electronic device 100 has opposite first and second (e.g., bottom and top) sides 101 and 102, respectively, which are spaced apart from one another along the third direction Z in the illustrated position in FIG. 1. The electronic device 100 also has laterally opposite third and fourth sides 103 and 104 that are spaced apart from one another along the first direction X, and fifth and sixth sides 105 and 106 (FIG. 1A) that are spaced apart from one another along the second direction Y in the illustrated position.

The electronic device 100 includes conductive leads 107 and a package structure 108 that encloses portions of the leads 107 and encloses a non-conductive die attach film 109 that attaches a semiconductor die 110 to some of the leads 107. The leads 107 in one example are or include conductive metal, such as copper, aluminum, etc. The non-conductive die attach film 109 can be any low electrical conductivity adhesive material that attaches the semiconductor die 110 to one or more conductive leads 107. The package structure 108 in one example is a generally rectangular plastic molded structure and defines approximately planar bottom, top and lateral sides 102-106, although not a requirement of all possible implementations. The illustrated example has the semiconductor die 110 attached to portions of four conductive leads 107. In other examples, the semiconductor die 110 can be attached to more or fewer leads 107 or portions thereof using non-conductive die attach film 109.

The example electronic device 100 has a single semiconductor die 110. Other examples can include more than one semiconductor die 110. The semiconductor die 110 has a bottom or first side 121 (FIG. 1), a top or second side 122 (FIG. 1) and lateral sides 123, 124 (FIG. 1), 125 and 126 (FIG. 1A). The first side 121 of the semiconductor die 110 extends at least partially on the top side of the non-conductive die attach film 109. The first side 121 of the semiconductor die 110 is a die back side, and the second side 122 is a die front side with conductive features 111 (FIG. 1) such as copper or aluminum bond pads, studs, pillars, or other conductive terminals. At least some of the conductive features 111 are electrically connected to respective ones or groups of the conductive leads 107 in one example. The conductive features 111 provide electrical connections to one or more components and/or circuits in the semiconductor die 110, such as resistors, transistors, diodes, capacitors, inductors, etc. (not shown). The package structure 108 encloses the semiconductor die 110, the non-conductive die attach film 109 and portions of the respective conductive leads 107.

The electronic device 100 in one example includes bond wires 112 (e.g., conductive aluminum, copper, etc.) connected between respective conductive leads 107 and conductive features 111 of the semiconductor die 110. The conductive features 111 and bond wires 112 provide electrical connections between the component(s) or circuit(s) of the semiconductor die 110 and a host circuit board 130 or system (FIG. 1) in which the electronic device 100 is installed. In other examples, different electrical interconnection types and forms can be provided, such as flip-chip attachments, substrates, clips, etc. (not shown) alone or in combination with one or more bond wires 112. In the illustrated example, the two laterally opposite leads 107 shown in the section view of FIG. 1 are each connected by a bond wire 112 to a respective one of the conductive features 111 of the top side 122 of the semiconductor die 110 and the device includes several interconnections of conductive die features 111 to respective ones of the leads 107 as shown in FIG. 1A.

The non-conductive die attach film 109 extends on a portion of the top side of the attached conductive leads 107 and on a portion of the bottom or first side 121 of the semiconductor die 110. The non-conductive die attach film 109 extends at least partially between the associated conductive leads 107 and the first side 121 of the semiconductor die 110 along the third direction Z. A portion of the non-conductive die attach film 109 can extend on a portion of one or more lateral sides of the conductive leads 107, for example, as shown in FIG. 1, although not a requirement of all possible implementations.

The non-conductive die attach film 109 has a thickness T1, T2 (FIG. 1). The non-conductive die attach film 109 in the illustrated example has a portion that does not engage an underlying lead 107 with a first thickness T1 along the third direction Z, for example, between the laterally spaced conductive leads 107 as shown in FIG. 1. The non-conductive die attach film 109 has a second portion that extends along the third direction Z between a portion of the top side of a conductive lead 107 and the first side 121 of the semiconductor die 110 and has a smaller second thickness T2 as shown in FIG. 1. In one example, the difference in the thicknesses T1 and T2 at least partially results from compressive downward force applied to the semiconductor die 110 during attachment to the leads 107 in manufacturing of the electronic device 100.

The non-conductive die attach film 109 extends between the conductive lead 107 and the semiconductor die 110 with one or more lateral sides 123-126 of the semiconductor die 110 extending beyond a lateral end of the non-conductive die attach film 109 by a non-zero gap distance G as shown in FIGS. 1 and 1A. In one example, the gap distance G is approximately 10-12 um. The separate singulation or separation of the non-conductive die attach film 109 by a first singulation process and singulation or separation of the semiconductor die 110 from a starting wafer by a second singulation process provides independent control of the lateral widths of the semiconductor die 110 and the non-conductive die attach film 109. This facilitates providing the semiconductor die overhang by the gap distance G in certain examples.

The electronic device 100 is shown in FIG. 1 in a system having a circuit board 130 with one or more conductive features 132, such as conductive metal pads. The electronic device 100 in this example has one or more of the conductive leads 107 connected to respective ones of the conductive feature 132 of the circuit board 130, for example, by solder connections to attach the device 100 to the circuit board and to form one or more electrical connections between one or more components and/or circuits of the semiconductor die 110 and a component or circuit of the circuit board 130.

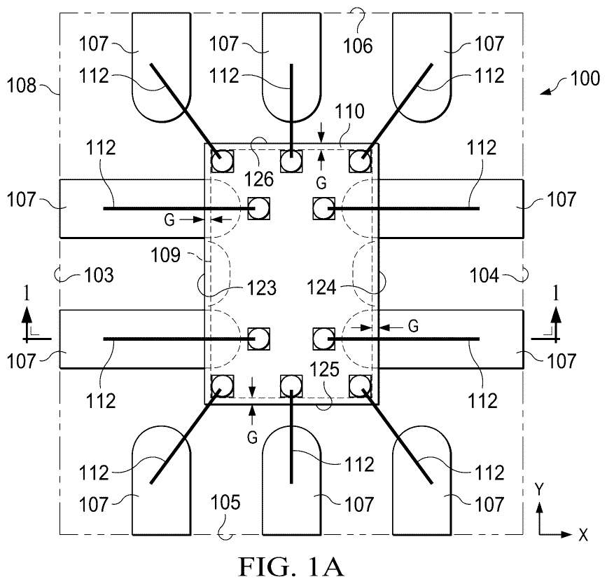

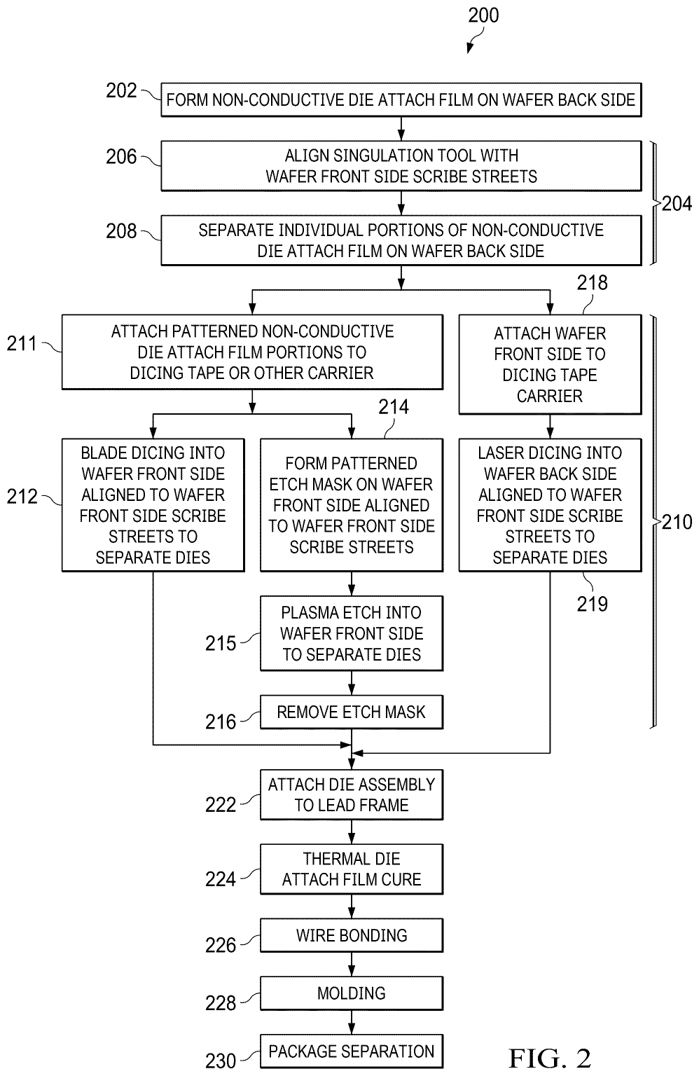

Referring also to FIGS. 2-17, FIG. 2 shows a method 200 of making an electronic device and FIGS. 3-17 show the example electronic device 100 of FIGS. 1 and 1A undergoing fabrication processing according to an implementation of the method 200.

The method 200 in one example includes forming a non-conductive die attach film on the back side of a wafer at 202 in FIG. 2 followed by singulating the die attach film on the wafer at 204. FIG. 3 shows one example, in which a material formation process 300 is performed that forms a non-conductive die attach film 109 on wafer 301 to a thickness T1 (e.g., approximately 10-50 μm average thickness along the third direction Z in the illustrated orientation). The wafer 301 has a first side 321 (e.g., a back or bottom side) and an opposite second side 322 (e.g., a front side or top side). The wafer 301 has markings or features M in prospective die areas 306 along the second side 322, such as visually or optically discernible markings or structural features, spaced from one another by a spacing distance S2. The markings M on the second side 322 in one example include bond pads or other conductive features or terminals (not shown in FIG. 3) that provide electrical connection to one or more components are circuits in each of a number of prospective die areas 306 of the wafer 301.

The front side 322 of the wafer 301 also has scribe street locations SS that extend between adjacent prospective die areas 306 along the second side 322. In one example, the material formation process 300 is a lamination process that includes placement and rolling of a laminate layer of non-conductive die attach film 109 to the thickness T1 on the back or bottom surface or side 321 of the wafer 301. In one implementation, the prospective die areas 306 are disposed in rows and columns along the top or second side 322 of the wafer 301 and the exposed scribe street portions SS of the second wafer side 322 extend along approximately parallel directions between adjacent prospective die areas 306.

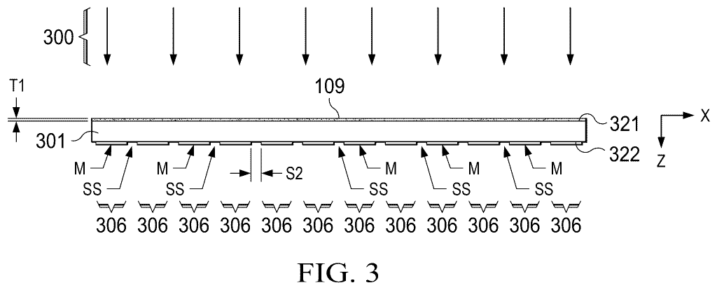

The method 200 in FIG. 2 includes singulating the die attach film on the wafer at 204. The illustrated implementation includes aligning a singulation tool by locating one or more of the scribe street locations SS along the second side 322 of the wafer 301 (e.g., at 206 in FIG. 2) before performing a first singulation process at 208. FIGS. 4 and 4A show one example, in which an alignment process 400 is performed (FIG. 4) that locates the scribe street locations SS using one or more cameras 411 and 412. The illustrated alignment process 400 uses an automated position controller 410 with one or more cameras 411 and 412 to align a singulation tool 402 (e.g., a cutting blade, laser, etc.) positioned above the wafer back or first side 321 with respect to the markings or features M and/or the scribe street locations SS of the wafer front or second side 322 (e.g., FIG. 4A) prior to die attach film singulation. In one implementation, the first camera 411 is an infrared (IR) camera that locates the position of the wafer 301 in first and second directions (e.g., the illustrated X direction and an orthogonal second direction Y, not shown in FIG. 4). In one example, the first camera 411 views the markings M and/or the scribe streets SS through the die attach film 109 and through the wafer 301 along the third direction Z to locate (e.g., determine the special position of) the scribe streets SS of the wafer 301. In one example, the desired locations along the first side 321 of the wafer 301 from which the die attach film 109 is to be removed correspond to (e.g., are vertically aligned with, such as directly above) the scribe street locations SS along the second side 322.

In this or another implementation, one or more further optical cameras 412 can be used to facilitate alignment of the singulation tool 402 with respect to the scribe street positions SS. The second camera 412 in one example locates the scribe street positions SS in the X and Y directions, for example, by viewing the optically discernible markings M and/or discernible features of the scribe street locations SS along the front or second side of the wafer 301. The controller 410 uses the scribe street location information to align the tool 402 with the desired material removal areas, for example, while translating the tool 402 in the X and Y directions to selectively remove portions of the non-conductive die attach film 109. This allows the non-conductive die attach film 109 to be selectively removed at the exact position that matches scribe street locations SS by camera alignment to help improve productivity and promote or ensure complete separation.

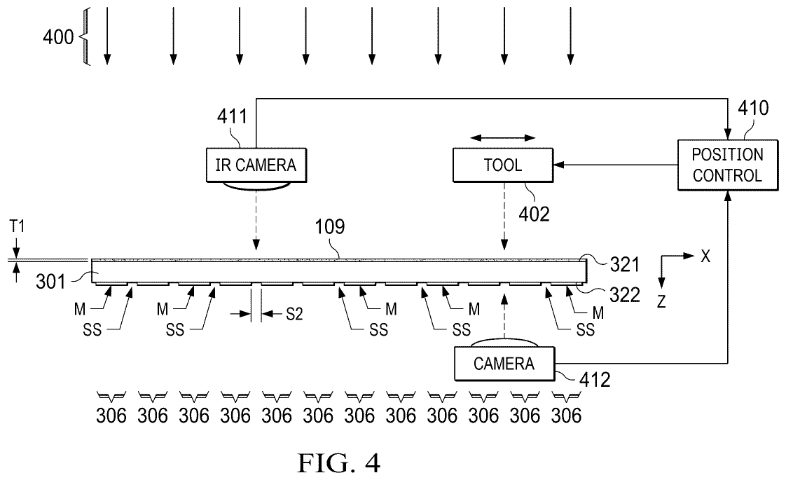

The method 200 in this example includes die attach film singulation (e.g., DAF singulation) at 208 in FIG. 2. FIG. 5 shows one example, in which a die attach film singulation or separation process 500 is performed that singulates individual portions of the non-conductive die attach film 109 to separate the portions from one another on the first side 321 of the wafer 301. The DAF singulation process 500 creates a pattern of separated portions of the non-conductive die attach film 109 individually corresponding to respective one of the prospective die areas 306. The first singulation process 500 in one implementation selectively removes the non-conductive die attach film 109 on the side 321 of a wafer 301 above the scribe street locations SS along the second side 322 of the wafer 301 by automated translation of the tool 402 by the controller 410 based on scribe street locations SS using one or both of the cameras 411 and/or 412.

As further shown in FIG. 5, the first singulation process 500 creates gaps of a first spacing distance S1 between adjacent ones of the separated portions of the non-conductive die attach film 109. In one example, the first spacing distance S1 is approximately 30 μm or more and approximately 40 μm or less. Any suitable process 500 can be used that separates individual portions of the non-conductive die attach film 109 to separate the portions from one another on the wafer 301. The first singulation process 500 in one example is a blade dicing process using a cutting blade to separate the portions of the non-conductive die attach film 109 on the side 321 of the wafer 301. In another example, the first singulation process 500 is a laser dicing process using a laser to separate the portions of the non-conductive die attach film 109 on the side 321 of the wafer 301. These or other types of separation process 500 can be used alone or in combination to form the non-conductive die attach film portions 109 on the wafer 301.

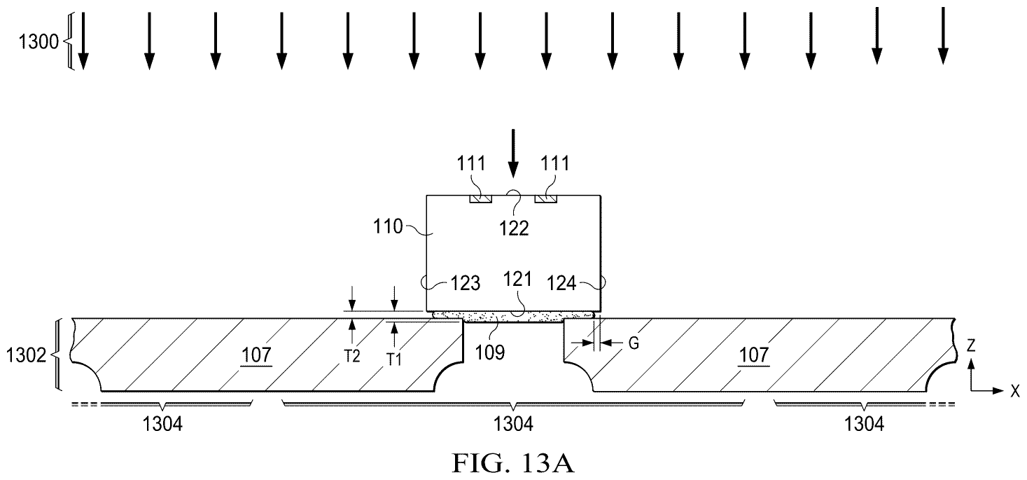

The method 200 continues with a second singulation process at 210 in FIG. 2 to separate one or more individual semiconductor dies 110 from the wafer 301. The separated or singulated semiconductor dies 110 each have a bottom or first side 121 with a respective separated portion of the non-conductive die attach film 109. The separated dies 110 each have an opposite top or second side 122 with respective ones of the conductive features 111 (e.g., bond pads) as discussed above in connection with FIGS. 1 and 1A. The second singulation process at 210 provides separated die assemblies that each includes bottom side portions of the non-conductive die attach film 109 which can them be removed from the carrier 602 for attachment to a lead frame during packaging operations as described further below in connection with FIGS. 13-17.

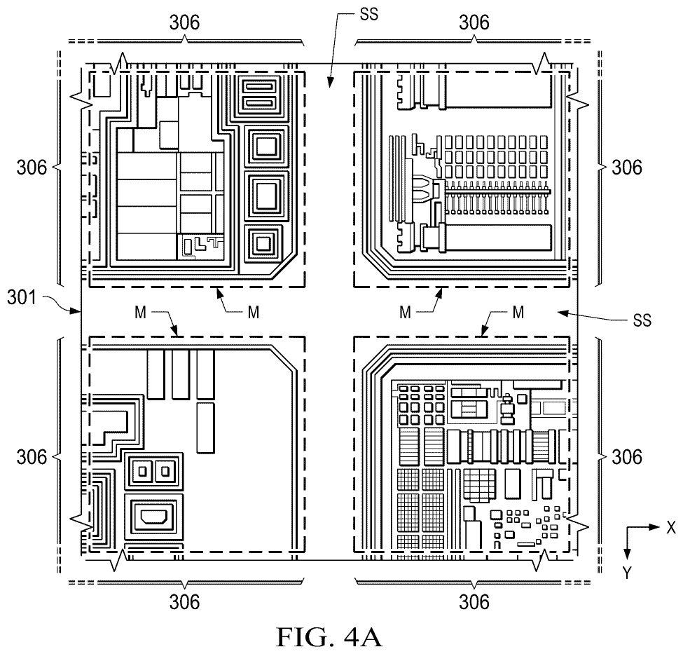

In certain examples, before die singulation, the separated portions of the non-conductive die attach film 109 are attached to a carrier at 211 in FIG. 2. FIG. 6 shows one example, in which an attachment process 600 is performed that attaches the separated portions of the non-conductive die attach film 109 to a carrier 601, such as a ring frame. In one example, the carrier 601 includes a carrier tape structure 602, such as a dicing tape installed on the ring frame with a flat or approximately planar top surface to which the non-conductive die attach film portions are attached using automated pick and place equipment (not shown).

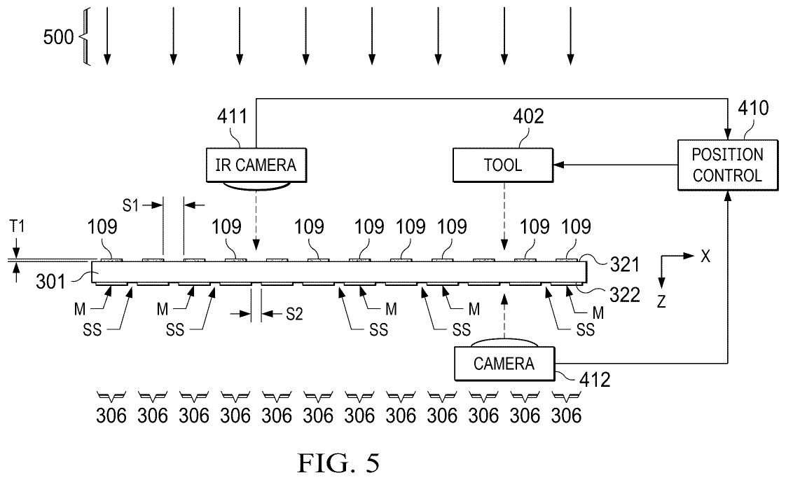

At 212 in FIG. 2, the method 200 in one example includes performing a second singulation process that separates the semiconductor dies 110 from the wafer 301 with respective separated portions of the non-conductive die attach film 109. FIG. 7 shows one example, in which a second singulation process 700 is performed with the separated portions of the non-conductive die attach film 109 on the carrier 602. In one example, the second singulation process 700 is a blade dicing process 700 using a cutting blade (not shown) that cuts from the second side 322 to separate the semiconductor dies 110 from the wafer 301. The second singulation process 700 creates gaps of the second spacing distance S2 between adjacent semiconductor dies 110 separated from the wafer 301. In one example, the first spacing distance S1 (e.g., approximately 30 to 40 μm) is greater than the second spacing distance S2 between the separated semiconductor dies 110. In certain examples, the second spacing distance S2 is approximately 2 microns or more and approximately 10 μm or less. In one example, the second singulation process 700 can optionally include stretching of the carrier tape 602 (not shown) to promote die separation from the starting wafer structure.

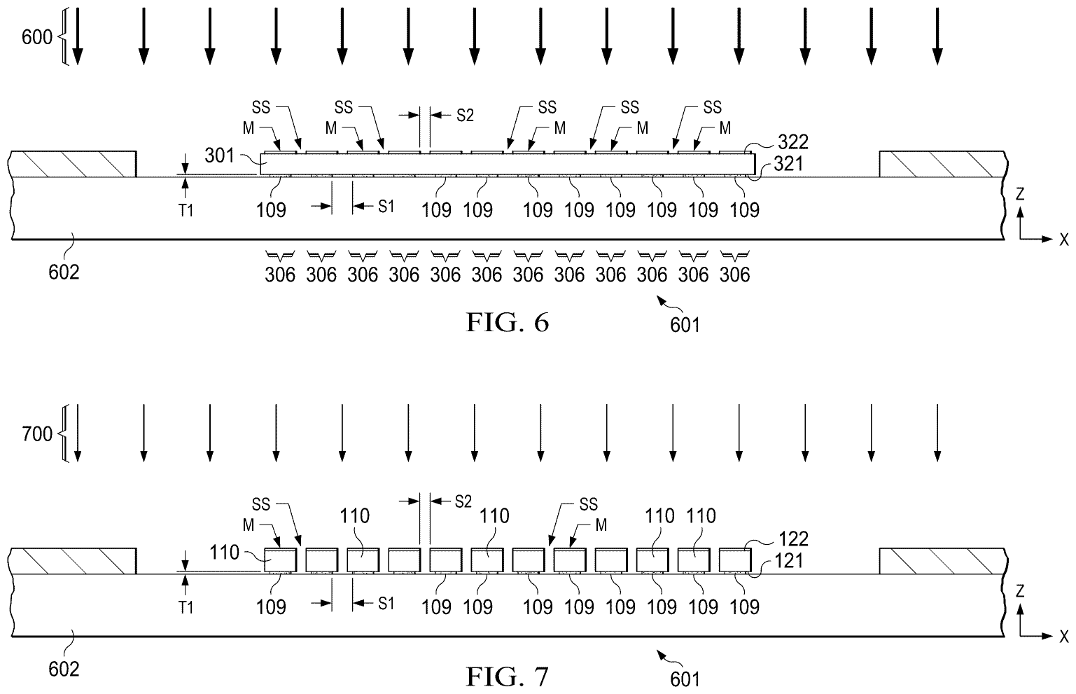

In another implementation, the second singulation process at 210 in FIG. 2 includes die singulation at 214-216 using etching steps from the wafer second side 322, after the separated portions of the non-conductive die attach film 109 are attached to the carrier 602 at 211. An etch mask is formed at patterned at 214. FIG. 8 shows one example, in which an etch mask 802 is formed (e.g., deposited) on the wafer second side 322 and patterned while the separated portions of the non-conductive die attach film 109 are attached to the carrier 602 at 211. In another example, the etch mask 802 can be formed and patterned along the second side 322 of the wafer 301 during wafer processing before wafer and die attach film attachment to the carrier 601.

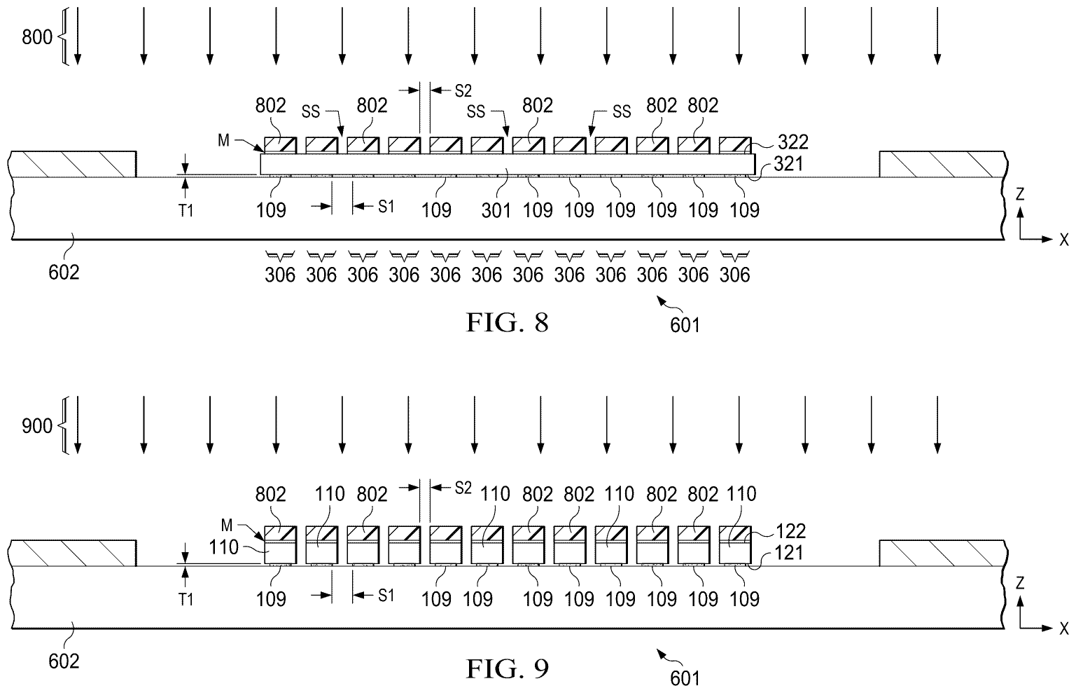

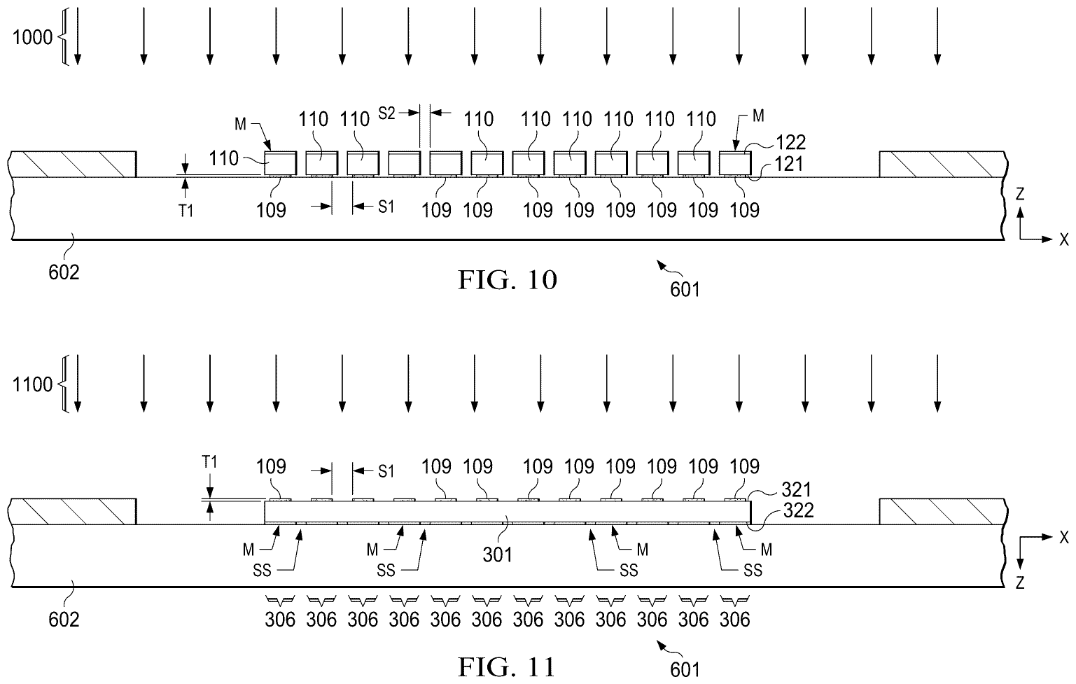

At 215 in FIG. 2, the second singulation process includes etching. FIG. 9 shows one example, in which an etch process 900 is performed using the etch mask 802 to separate the semiconductor dies 110 from the wafer. In one implementation, the etch process 900 is a plasma etch process. The etch process 900 in this example creates gaps of the second spacing distance S2 between the adjacent separated semiconductor dies 110 (e.g., approximately 2 microns or more and approximately 10 μm or less). In one example, the second singulation process 900 can optionally include stretching of the carrier tape 602 (not shown) to promote die separation from the starting wafer structure. In one example, the etch mask is removed at 216 in FIG. 2. FIG. 10 shows one example, in which a mask stripping or other removal process 1000 is performed that removes the etch mask from the top or second sides 122 of the separated semiconductor dies 110.

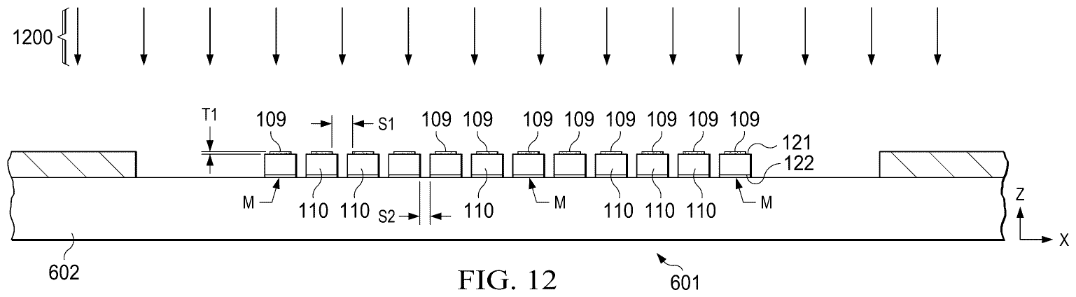

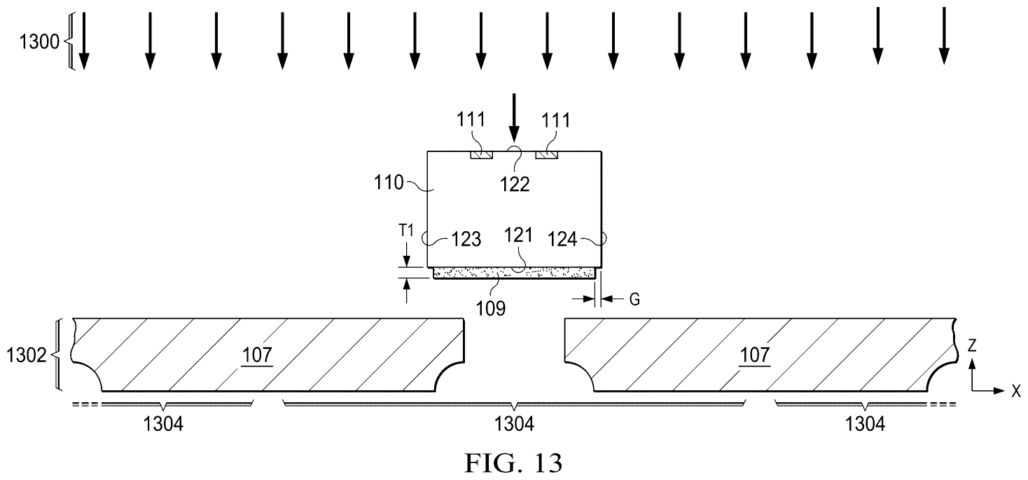

In yet another example, the second singulation process at 210 in FIG. 2 includes die singulation at 214-216 using laser dicing at 218 and 219. In this example, the wafer front side is attached to a carrier at 218. FIG. 11 shows one example, in which an attachment process 1100 is performed that attaches the second side 322 of the wafer 301 to the carrier tape 602. At 219 in FIG. 2, the second singulation process at 210 in this example includes laser dicing. FIG. 12 shows one example, in which a laser dicing process 1200 is performed from the first side 321 of the wafer 301 using a laser (not shown) to separate the semiconductor dies 110 from the wafer 301. The laser dicing process 1200 creates gaps of the second spacing distance S2 between the adjacent separated semiconductor dies 110 (e.g., approximately 2 microns or more and approximately 10 μm or less). In one example, this implementation of the second singulation process 1200 can optionally include stretching of the carrier tape 602 (not shown) to promote die separation from the starting wafer structure.

Other forms and types of separation processing can be used to implement the second singulation process at 210 in FIG. 2. The second singulation process at 210 provides separated die assemblies 110, 109 that individually include bottom side portions of the non-conductive die attach film 109 which can them be removed from the carrier 602 for attachment to a lead frame during packaging operations. In certain implementations, the removal of the individual die assemblies 110, 109 from the carrier structure 601 can include optional activation or release processing (e.g., thermal, ultraviolet, etc., not shown) to facilitate detachment of the bottom sides of the separated portions of the non-conductive die attach film 109 from the carrier tape 602. Optional release processing can help subsequent removal of the individual die assemblies including the separated semiconductor die 110 and the attached patterned portion of the non-conductive die attach film 109, for example, using pick and place equipment (not shown). The die assemblies 110, 109 can be stored for later attachment to a lead frame during subsequent electronic device packaging operations, or a single operation can remove the separated die assemblies from the carrier tape 602 for automated translation and placement on a lead frame panel array in a single operation.

The method 200 continues at 222 in FIG. 2 with attaching the separated semiconductor dies 110 and associated non-conductive die attach film portion 109 to a lead frame with the separated portion of the non-conductive die attach film 109 extending between a prospective lead portion of the lead frame and the bottom or first side 121 of the semiconductor die 110. FIGS. 13 and 13A illustrate one example, in which a die attach process 1300 is performed (e.g., using automated pick and place equipment, not shown) using a lead frame panel array 1302. The lead frame panel array 1302 in one example has rows and columns of unit areas 1304 disposed in rows and columns of a panel array structure, a portion of which is shown in FIGS. 13 and 13A. In one example, the process 1300 positions individual semiconductor die assemblies in corresponding unit areas 1304 of the array structure, with automated location in first and second (e.g., X and Y) directions, and then translation of the die assembly downward in the direction of the arrow in FIGS. 13 and 13A (e.g., along the third direction Z). The process 1300 attaches the separated portion of the non-conductive die attach film 109 of the separated semiconductor die 110 to one or more prospective conductive leads 107 of a lead frame 1302.

As shown in FIG. 13, the patterned non-conductive die attach film portion 109 has the initial first thickness T1 along the third direction Z (e.g., controlled by the deposition or lamination or other die attach film formation process used at 202 in FIG. 2) prior to attachment to the lead frame panel array 1302. As shown in FIG. 13A, the attachment process 1300 in one example includes applying a downward force to a singulated semiconductor die 110 while attaching the separated portion of the non-conductive die attach film 109 to one or more prospective conductive leads 107 of the lead frame 1302. In certain implementations, the applied downward force can compress the singulated portion of the non-conductive die attach film 109 that engages the top side of the prospective lead or leads to a smaller second thickness T2 (FIG. 13A). In the illustrated example, the downward force during die attachment is controlled to leave the lateral spacing of the non-conductive die attach film 109 by the gap distance G inward from the associated lateral edge or side of the semiconductor die 110 (e.g., sides 123 and 124 in the views of FIGS. 13 and 13A).

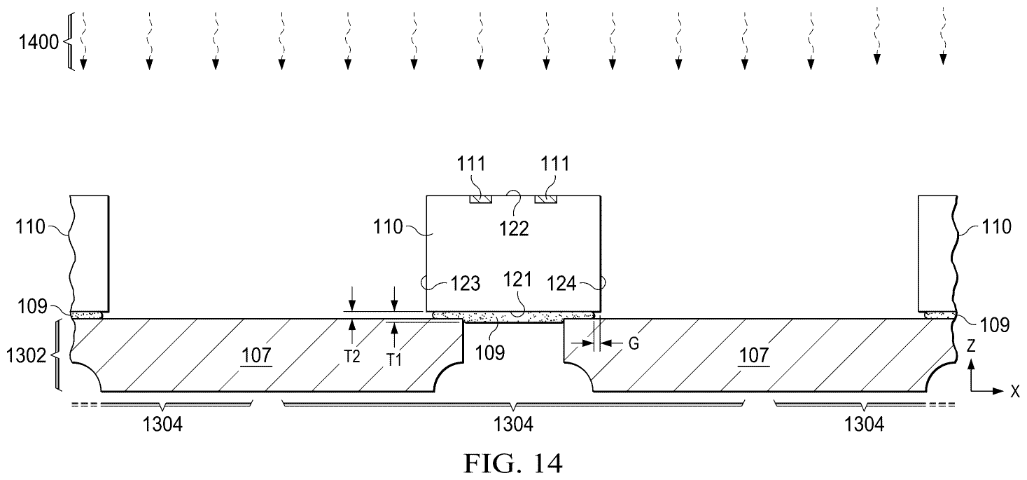

In one example, the method 200 includes die attach curing at 224 in FIG. 2. FIG. 14 shows one example, in which a thermal curing process 1400 is performed that cures the die attach film 109 to promote adhesion of the die attach film 109 and the associated semiconductor dies 110 to the conductive features (e.g., prospective leads) of the lead frame panel array 1302. In another implementation, the thermal curing process at 224 can be omitted.

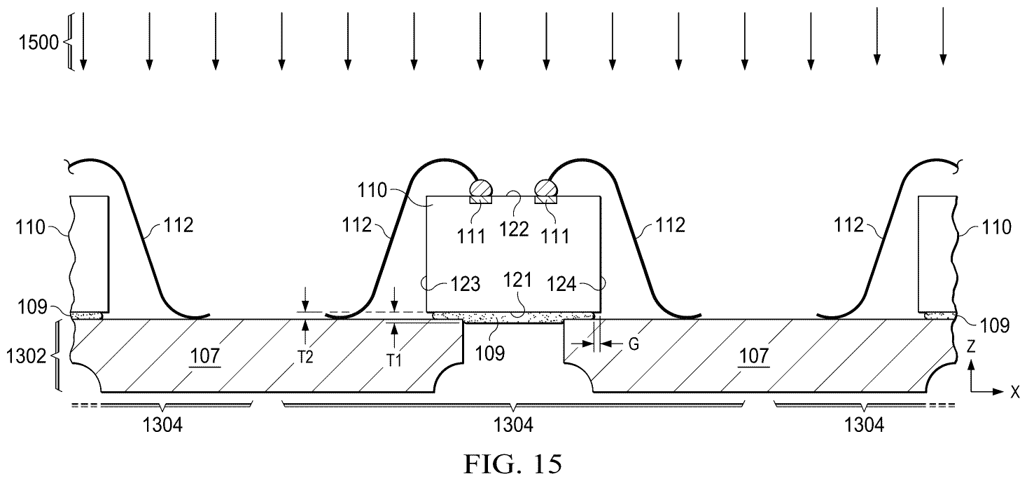

The method 200 continues at 226 in FIG. 2 with electrical connection processing to form one or more electrical connections between a circuit and/or component of the individual attached semiconductor dies 110 and prospective leads of the lead frame panel array 1302. FIG. 15 shows one example, in which a wire bonding process 1500 is performed that forms the bond wires 112 between respective ones of the conductive features 111 (e.g., bond pads) of the semiconductor die 110 and one of the prospective lead portions of the lead frame panel array 1302 in each of the unit areas 1304 of the array structure. In other implementations, other types and forms of electrical connection processing can be performed, for example, using conductive metal clips, flip-chip electrical interconnections (not shown) alone or in combination with wire bonding.

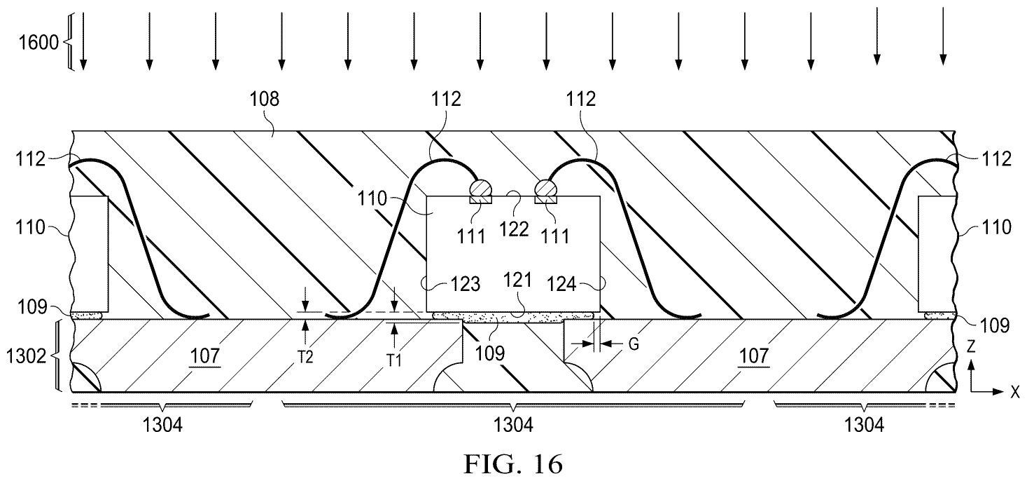

The method 200 continues at 228 in FIG. 2 with package formation. FIG. 16 shows one example, in which a molding process 1600 is performed using suitable mold structures (not shown) to form the package structure 108 that encloses the semiconductor dies 110, the bond wires 112, the die attach film portions 109, and upper portions of the prospective conductive lead features of the lead frame panel array 1302. In one example, a single mold cavity can be used to create a unitary molded package structure 108 that extends across multiple rows and/or columns of the lead frame panel array structure. In other implementations, separate die cavities can be used (not shown), for example, to create molded package structures 108 that are individually associated with a corresponding one of the unit areas 1304, or multiple mold cavities can be used that extend across multiple unit areas (e.g., rows or columns) of the array structure.

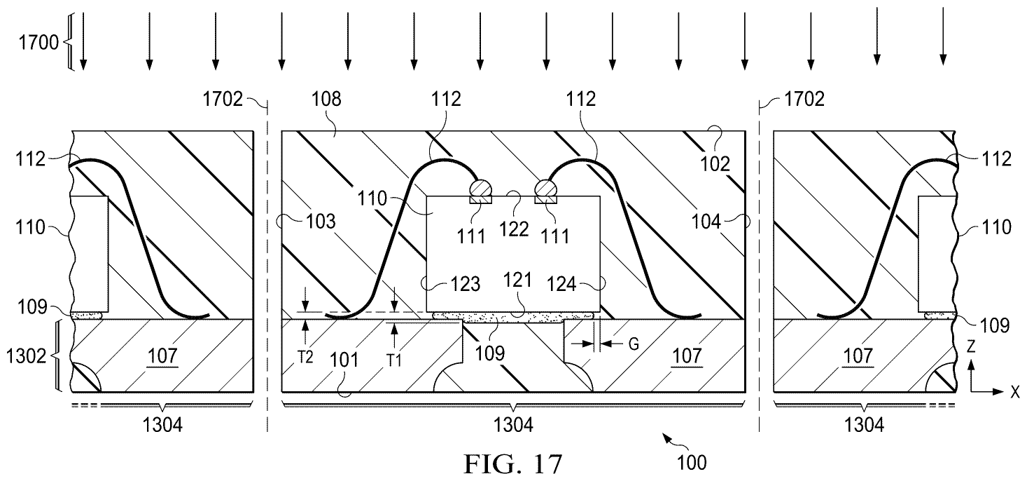

The method 200 in FIG. 2 continues at 230 with package separation processing. FIG. 17 shows one example, in which a package separation process 1700 is performed that separates individual finished packaged electronic devices 100 from one another and from the starting lead frame panel array structure. The illustrated example separates the individual packages and the conductive metal features of the lead frame along separation lines 1702, for example, along rows and columns between adjacent unit areas 1304 of the array structure. Any suitable separation process 1700 can be used, for example, saw cutting, laser cutting, chemical etching, etc. or combinations thereof. The separation process 1700 cuts through certain portions of the starting lead frame structure, and creates approximately planar lateral sides (e.g., 103-106) of the electronic devices 100 including sides of the package structure 108 and the conductive metal leads 107 as shown in FIGS. 1, 1A and 17.

The described techniques and devices facilitate package size reduction, for example, in chip on lead packaged electronic devices that need not have a dedicated die attach pad as part of a lead frame, and a semiconductor die 110 is attached directly on one or more leads 107. The described examples help mitigate or avoid creation of silicon particles embedded within a die attach film, and thus facilitate electrical isolation between the attached semiconductor die 110 and conductive metal leads 107 of the finished packaged electronic device 100. These advantages allow use of conductive metal leads both for supporting an attached semiconductor die 110 and carrying signals that can have voltages different from a voltage of the silicon of the semiconductor die 110 during operation when installed in a host system (e.g., FIG. 1 above).

The above examples are merely illustrative of several possible implementations of various aspects of the present disclosure, wherein equivalent alterations and/or modifications will occur to others skilled in the art upon reading and understanding this specification and the annexed drawings. Modifications are possible in the described examples, and other implementations are possible, within the scope of the claims.

What is claimed is:

1. An electronic device, comprising:
a conductive lead;
a semiconductor die;
a package structure enclosing the semiconductor die and a portion of the conductive lead; and
a non-conductive die attach film extending between the conductive lead and the semiconductor die, wherein a lateral side of the semiconductor die extending beyond an end of the non-conductive die attach film by a non-zero gap distance.

2. The electronic device of claim 1, wherein the gap distance is approximately 10-12 um.

3. A system, comprising:
a circuit board with a conductive feature; and
an electronic device, comprising a conductive lead connected to the conductive feature of the circuit board, a semiconductor die, a package structure enclosing the semiconductor die and a portion of the conductive lead, and a non-conductive die attach film extending between the conductive lead and the semiconductor die, wherein a lateral side of the semiconductor die extending beyond an end of the non-conductive die attach film by a non-zero gap distance.

4. The system of claim 3, wherein the gap distance is approximately 10-12 um.

5. A method of fabricating an electronic device, the method comprising:
performing a first singulation process that separates portions of a non-conductive die attach film on a side of a wafer;
after the first singulation process, performing a second singulation process that separates a semiconductor die from the wafer, the semiconductor die having a side with a respective separated portion of the non-conductive die attach film; and
attaching the semiconductor die to a lead frame with the separated portion of the non-conductive die attach film extending between a prospective lead portion of the lead frame and the side of the semiconductor die.

6. The method of claim 5, further comprising, before performing the first singulation process, forming the non-conductive die attach film on the side of the wafer.

7. The method of claim 6, wherein forming the non-conductive die attach film includes rolling a laminate layer of the non-conductive die attach film on the side of the wafer.

8. The method of claim 5, comprising performing the second singulation process with the wafer or the separated portions of the non-conductive die attach film on a carrier.

9. The method of claim 5, wherein:
the first singulation process creates gaps of a first spacing distance between adjacent ones of the separated portions of the non-conductive die attach film;
the second singulation process creates gaps of a second spacing distance between adjacent semiconductor dies separated from the wafer; and
the first spacing distance is greater than the second spacing distance.

10. The method of claim 9, wherein:
the first spacing distance is approximately 30 μm or more and approximately 40 μm or less; and
the second spacing distance is approximately 2 microns or more and approximately 10 μm or less.

11. The method of claim 5, wherein the first singulation process is a blade dicing process using a cutting blade to separate the portions of the non-conductive die attach film on the side of the wafer.

12. The method of claim 5, wherein the first singulation process is a laser dicing process using a laser to separate the portions of the non-conductive die attach film on the side of the wafer.

13. The method of claim 5, wherein the second singulation process is a blade dicing process using a cutting blade to separate the semiconductor die from the wafer.

14. The method of claim 13, further comprising:
before performing the blade dicing process, attaching the separated portions of the non-conductive die attach film to a carrier; and
performing the blade dicing process using the cutting blade from an opposite second side of the wafer.

15. The method of claim 5, wherein the second singulation process is an etch process using an etch mask to separate the semiconductor die from the wafer.

16. The method of claim 15, further comprising:
before performing the etch process, attaching the separated portions of the non-conductive die attach film to a carrier;
forming and patterning the etch mask on an opposite second side of the wafer;
performing the etch process from the second side of the wafer to separate the semiconductor die from the wafer; and
removing the etch mask from the second side of the wafer.

17. The method of claim 5, wherein the second singulation process is a laser dicing process using a laser to separate the semiconductor die from the wafer.

18. The method of claim 17, further comprising:
before performing the laser dicing process, attaching an opposite second side of the wafer to a carrier; and
performing the laser dicing process using the laser from the side of the wafer.

19. The method of claim 5, further comprising:
before performing the first singulation process, locating scribe street locations along an opposite second side of the wafer; and
performing the first singulation process to selectively remove the non-conductive die attach film on the side of a wafer above the scribe street locations along the second side of the wafer.

20. The method of claim 19, wherein the scribe street locations are located using an infrared camera.
